(19) United States
(12) Patent Application Publication
(10) Pub. No.: US 2024/0379887 A1
(43) Pub. Date: Nov. 14, 2024

(54) SOLAR CELL AND SOLAR CELL MANUFACTURING METHOD

(71) Applicants: KABUSHIKI KAISHA TOSHIBA, Tokyo (JP); TOSHIBA ENERGY SYSTEMS & SOLUTIONS CORPORATION, Kawasaki-shi (JP)

(72) Inventors: Miyuki Shiokawa, Kawasaki Kanagawa (JP); Katsuya Yamashita, Yokohama Kanagawa (JP); Takeshi Gotanda, Yokohama Kanagawa (JP); Tomohiro Tobari, Yokohama Kanagawa (JP); Yutaka Saita, Yokohama Kanagawa (JP)

(21) Appl. No.: 18/780,579

(22) Filed: Jul. 23, 2024

Related U.S. Application Data
(63) Continuation of application No. PCT/JP2022/002578, filed on Jan. 25, 2022.

(51) Int. Cl. H01L 31/048

(52) U.S. Cl. CPC H01L 31/0481

(57) ABSTRACT

A solar cell of an embodiment includes a first solar cell panel, a second solar cell panel, a first sealing layer, a second sealing layer, a third sealing layer, and a first protective member. A thickness of the first sealing layer is 50 μm or more and 400 μm or less. A thickness of the second sealing layer is 30 μm or more and 400 μm or less. A thickness of the third sealing layer is 50 μm or more and 400 μm or less. A thickness of the first protective member is 25 μm or more and 200 μm or less. A thickness of the solar cell is 350 μm or more and 1140 μm or less at a portion at which the first solar cell panel and the second solar cell panel overlap each other.

### CROSS-REFERENCE TO RELATED APPLICATION

This is a Continuation application of International Application No. PCT/JP2022/002578, filed on Jan. 25, 2022, and the entire contents of the aforementioned application are incorporated herein by reference.

### FIELD

Embodiments of the present invention relate to a solar cell and a solar cell manufacturing method.

### BACKGROUND

There is a tandem type solar cell in which solar cell panels are stacked. The tandem type solar cell includes a first solar cell panel and a second solar cell panel of a light transmitting type stacked on a light receiving surface side of the first solar cell panel. The first solar cell panel and the second solar cell panel are formed of semiconductor materials having different absorption wavelength ranges from each other. Compared to the solar cell of the related art, the tandem type solar cell can convert light having a wide wavelength range into electrical energy and has high energy conversion efficiency. For this reason, the tandem type solar cell is suitable as a power source for a moving object such as an aircraft or a mobility vehicle.

Incidentally, in a case where the tandem type solar cell is mounted on the moving object or the like, the weight of the tandem type solar cell is restricted depending on a device on which the tandem type solar cell is mounted. The tandem type solar cell is formed by stacking a sealing member and a protective member on a solar cell panel, and thus there is room for improvement in the configurations of the sealing member and the protective member from the standpoint of reducing weight. However, when the tandem type solar cell is thinned to reduce its weight, unevenness may occur on a surface, which may reduce power generation efficiency.

### BRIEF DESCRIPTION OF THE DRAWINGS

FIG. 1 is a plan view showing a layer structure of a tandem type solar cell according to an embodiment.

FIG. 2 is a development view of the tandem type solar cell according to the embodiment.

FIG. 3 is a plan view showing a bottom module of the embodiment.

FIG. 4 is a plan view showing a top module of the embodiment.

FIG. 5 is a plan view showing a positional relationship between the bottom module and the top module of the embodiment.

FIG. 6 is a cross-sectional view of the tandem type solar cell along line VI-VI of FIG. 1.

FIG. 7 is a diagram showing an example of a heating step according to an embodiment.

FIG. 8 is a development view of a device including a tandem type solar cell according to a modification example of the embodiment.

### DETAILED DESCRIPTION

A solar cell of an embodiment includes a first solar cell panel, a second solar cell panel, a first sealing layer, a second sealing layer, a third sealing layer, and a first protective member. The second solar cell panel is a light transmitting type disposed to face a light receiving surface of the first solar cell panel. The first sealing layer is stacked on the second solar cell panel from a side opposite to the first solar cell panel. A thickness of the first sealing layer is 50 μm or more and 400 μm or less. The second sealing layer is disposed between the first solar cell panel and the second solar cell panel. The second sealing layer is stacked to be in direct contact with the first solar cell panel and the second solar cell panel. A thickness of the second sealing layer is 30 μm or more and 400 μm or less. The third sealing layer is stacked on the first solar cell panel from a side opposite to the second sealing layer. A thickness of the third sealing layer is 50 μm or more and 400 μm or less. The first protective member is stacked on the first sealing layer from a side opposite to the second solar cell panel. A thickness of the first protective member is 25 μm or more and 200 μm or less. A thickness of the solar cell is 350 μm or more and 1140 μm or less at a portion at which the first solar cell panel and the second solar cell panel overlap each other when viewed in a normal direction of a light receiving surface of the first solar cell panel.

Hereinafter, a solar cell and a solar cell manufacturing method of embodiments will be described with reference to the drawings. In the following description, the same reference signs are given to constituent elements having the same or similar functions. Further, duplicate description of those constituent elements may be omitted.

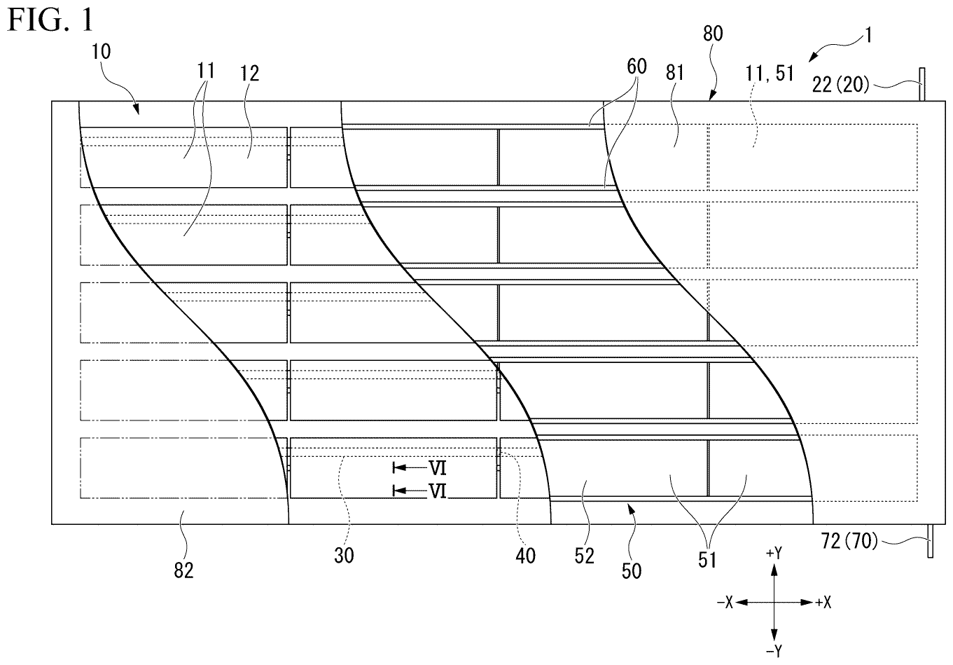

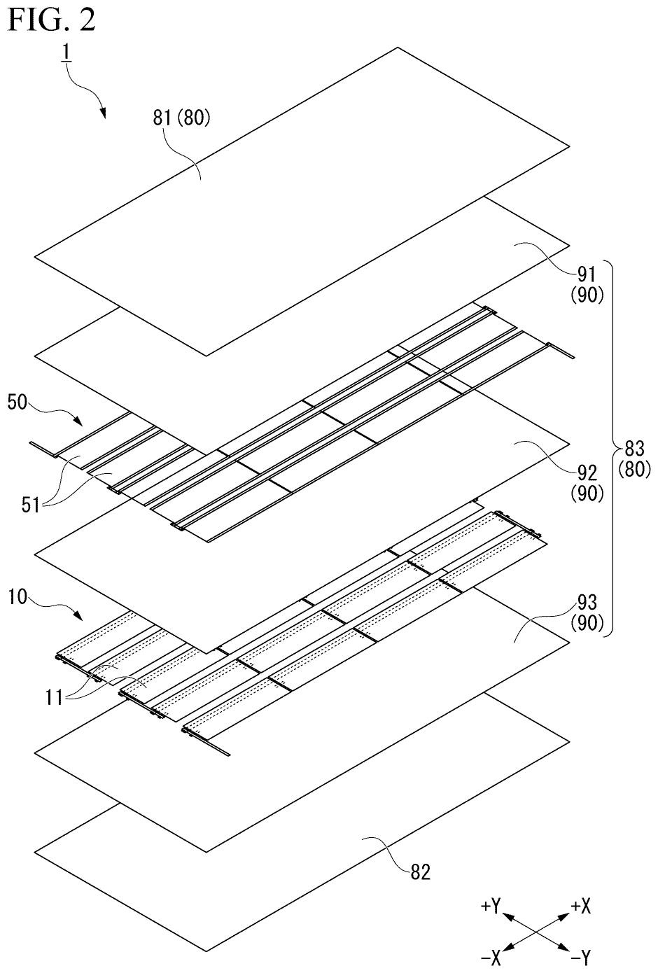

FIG. 1 is a plan view showing a layer structure of a tandem type solar cell according to an embodiment. FIG. 2 is a development view of the tandem type solar cell according to the embodiment. In FIG. 1, in order to show a stacked structure of the tandem type solar cell 1, some layers are cut away.

As shown in FIGS. 1 and 2, the tandem type solar cell 1 is formed in a rectangular plate shape. Hereinafter, a thickness direction of the tandem type solar cell 1 is simply referred to as a “thickness direction.” Here, for convenience of explanation, a +X direction, −X direction, +Y direction, and −Y direction orthogonal to the thickness direction will be defined. The −X direction is a direction opposite to the +X direction. In a case where the +X direction and the −X direction are not distinguished from each other, they are simply referred to as an “X direction.” The +Y direction and the −Y direction are directions orthogonal to the X direction. The −Y direction is a direction opposite to the +Y direction. In a case where the +Y direction and the −Y direction are not distinguished from each other, they are simply referred to as a “Y direction.” In addition, a side in one direction in the thickness direction is defined as a “front side,” and a side in a direction opposite to the front side is defined as a “back side.”

The tandem type solar cell 1 includes a bottom module 10 having a photovoltaic cell 12 that constitutes a back cell, a top module 50 having a photovoltaic cell 52 that is disposed on the front side of the bottom module 10 and constitutes a front cell, and a package 80 that houses the bottom module 10 and the top module 50. The tandem type solar cell 1 is a four-terminal type solar cell in which a current is extracted from each of the bottom module 10 and the top module 50.

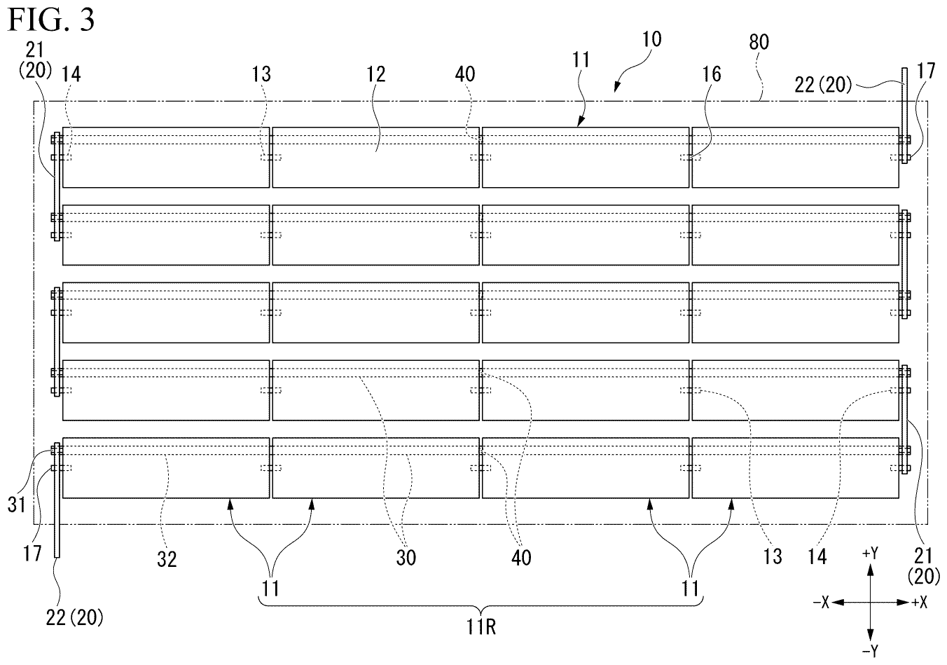

FIG. 3 is a plan view showing the bottom module of the embodiment. In FIG. 3, the outer shape of the package 80 is indicated by an imaginary line.

As shown in FIG. 3, the bottom module 10 includes a plurality of bottom solar cell panels 11 (first solar cell panels, other solar cell panels) connected to each other in series. All the bottom solar cell panels 11 are disposed along a common XY plane. At least one photovoltaic cell 12 is formed in the bottom solar cell panel 11. A single photovoltaic cell 12 may be formed in the bottom solar cell panel 11, or a plurality of photovoltaic cells 12 connected to each other in series and parallel may be formed in the bottom solar cell panel 11. The photovoltaic cell 12 is a silicon-based photovoltaic cell using Si that is an indirect transition semiconductor for a light absorbing layer. The photovoltaic cell 12 is, for example, a back-contact type crystalline silicon photovoltaic cell having an n-type electrode and a p-type electrode on the back side of the light absorbing layer. The photovoltaic cell 12 may be a photovoltaic cell of another type, such as a crystalline silicon photovoltaic cell. As the photovoltaic cell 12, for example, a silicon-based photovoltaic cell such as a single crystal, polycrystalline, heterojunction type, or amorphous photovoltaic cell, a CIS-based or CIGS-based compound photovoltaic cell, or the like is adopted. Furthermore, a cell electrode structure (a p-electrode and an n-electrode) of the photovoltaic cell 12 may be a combination of a metal wrap-through structure and a double-sided light receiving structure. The bottom solar cell panel 11 is disposed with a light receiving surface thereof oriented to the front side. That is, a normal direction of the light receiving surface of the bottom solar cell panel 11 is the thickness direction. Each bottom solar cell panel 11 is formed in a rectangular shape with a pair of sides extending in the X direction and the remaining pair of sides extending in the Y direction in a plan view seen in the thickness direction. In the present embodiment, each bottom solar cell panel 11 is formed in a rectangular shape with the X direction as a longitudinal direction in a plan view.

The bottom module 10 includes a plurality of bottom panel rows 11R (at least one first solar cell panel) each formed by a plurality of bottom solar cell panels 11 connected to each other in series. In each bottom panel row 11R, the bottom solar cell panels 11 are arranged in the X direction at intervals. The outer shape of the entire bottom panel row 11R is formed in a rectangular shape with the X direction as a longitudinal direction in a plan view. The bottom panel rows 11R are arranged in the Y direction at intervals. As a result, the plurality of bottom solar cell panels 11 are aligned in the X direction and the Y direction. The outer shape of the entire plurality of aligned bottom solar cell panels 11 is formed in a rectangular shape with the X direction as a longitudinal direction. In the illustrated example, the bottom module 10 includes five bottom panel rows 11R each formed by four bottom solar cell panels 11. However, the number of bottom solar cell panels 11 is not particularly limited. Hereinafter, with reference to the bottom panel row 11R positioned furthest in the +Y direction among the plurality of bottom panel rows 11R, the bottom panel row 11R located at an N-th position in the −Y direction is referred to as an “N-th bottom panel row 11R.” The same applies to a top panel row 51R, which will be described later.

The bottom solar cell panel 11 includes a negative electrode terminal 13 electrically connected to the n-type electrode and a positive electrode terminal 14 electrically connected to the p-type electrode. In a case where the photovoltaic cell 12 is a back-contact type photovoltaic cell, the negative electrode terminal 13 and the positive electrode terminal 14 are provided on the back surface of the bottom solar cell panel 11. The negative electrode terminal 13 is provided at an end portion of the bottom solar cell panel 11 in an odd-numbered bottom panel row 11R in the +X direction and is provided at an end portion of the bottom solar cell panel 11 in an even-numbered bottom panel row 11R in the −X direction. The positive electrode terminal 14 is provided at an end portion of each bottom solar cell panel 11 on a side opposite to the negative electrode terminal 13.

The bottom module 10 includes an interconnector 16, a panel row end connector 17, and a bottom bus bar 20.

The interconnector 16 connects adjacent bottom solar cell panels 11 in the bottom panel row 11R to each other in series. The interconnector 16 is formed of a metal plate. For example, the interconnector 16 is formed of a copper plate, a copper wire, or a copper foil having solder plated layers on both main surfaces. The interconnector 16 extends across a space between a pair of bottom solar cell panels 11 adjacent in the X direction in a plan view. The interconnector 16 is connected to the negative electrode terminal 13 of one bottom solar cell panel 11 and the positive electrode terminal 14 of the other bottom solar cell panel 11.

The panel row end connector 17 is connected to a terminal to which the interconnector 16 is not connected among the negative electrode terminal 13 and the positive electrode terminal 14 of the bottom solar cell panel 11 of each bottom panel row 11R. That is, the panel row end connector 17 is connected to each of the negative electrode terminal 13 and the positive electrode terminal 14, which are the electrical end portions of the bottom panel row 11R. The panel row end connector 17 is formed of a metal plate. For example, the panel row end connector 17 is formed of the same material as the interconnector 16. The panel row end connector 17 protrudes in the X direction from the bottom panel row 11R in a plan view.

The bottom bus bar 20 is disposed in the vicinity of the entire plurality of bottom solar cell panels 11 in a plan view. In the present embodiment, the vicinity of the entire plurality of bottom solar cell panels 11 is the vicinity of a single rectangular panel in a case where the plurality of bottom solar cell panels 11 are regarded as the single rectangular panel. The bottom bus bar 20 is formed of a metal plate. For example, the bottom bus bar 20 is formed of a copper plate having solder plated layers on both main surfaces. The bottom bus bar 20 extends in the Y direction. The bottom bus bars 20 are disposed not to come into contact with each other. The bottom bus bar 20 includes an inter-panel bus bar 21 and a terminal bus bar 22.

The inter-panel bus bar 21 connects the adjacent bottom panel rows 11R to each other in series via the panel row end connector 17. The inter-panel bus bars 21 are disposed on both sides of the bottom panel row 11R in the +X direction and the −X direction in a plan view. The inter-panel bus bar 21 in the +X direction connects an n-th bottom panel row 11R and an (n+1)-th bottom panel row 11R to each other in series, where n is an even number. Specifically, the inter-panel bus bar 21 in the +X direction is connected to the panel row end connector 17 in the +X direction connected to the n-th bottom panel row 11R and the panel row end connector 17 in the +X direction connected to the (n+1)-th bottom panel row 11R. The inter-panel bus bar 21 in the −X direction connects an m-th bottom panel row 11R and an (m+1)-th bottom panel row 11R to each other in series, where m is an odd number. Specifically, the inter-panel bus bar 21 in the −X direction is connected to the panel row end connector 17 in the −X direction connected to the m-th bottom panel row 11R and the panel row end connector 17 in the −X direction connected to the (m+1)-th bottom panel row 11R.

The terminal bus bar 22 is connected to the panel row end connector 17 that is not connected to the inter-panel bus bar 21 among the panel row end connectors 17. That is, when a plurality of bottom solar cell panels 11 connected to each other in series are regarded as one solar cell, the terminal bus bar 22 is connected to the negative electrode terminal 13 and the positive electrode terminal 14, which are the electrical end portions of the one solar cell, via the panel row end connector 17. The terminal bus bars 22 are disposed on both sides of the bottom panel row 11R in the +X direction and the −X direction in a plan view. The terminal bus bar 22 in the +X direction is connected to the panel row end connector 17 in the +X direction connected to a first bottom panel row 11R. The terminal bus bar 22 in the +X direction extends in the +Y direction from a connecting portion with the panel row end connector 17 and is drawn out of the package 80. In a case where the number of bottom panel rows 11R is N, the terminal bus bar 22 in the −X direction is connected to the panel row end connector 17 in the −X direction connected to an N-th bottom panel row 11R. The terminal bus bar 22 in the −X direction extends in the −Y direction from a connecting portion with the panel row end connector 17 and is drawn out of the package 80.

The bottom bus bar 20 extends in the +Y direction with respect to each bottom panel row 11R connected to the bottom bus bar 20. For example, the inter-panel bus bar 21 in the +X direction extends in the +Y direction with respect to an m-th bottom panel row 11R from a connecting portion with the m-th bottom panel row 11R and is connected to an (m−1)-th bottom panel row 11R, where m is an odd number. Further, the inter-panel bus bar 21 in the +X direction extends in the +Y direction with respect to the (m−1)-th bottom panel row 11R from a connecting portion with the (m−1)-th bottom panel row 11R.

The bottom module 10 includes the flexible substrate 30 and a bypass diode 40. The flexible substrate 30 is provided for each bottom panel row 11R. The flexible substrate 30 is connected to the bottom panel row 11R in parallel to form a bypass line for the bottom panel row 11R. The flexible substrate 30 is connected to the negative electrode terminal 13 and the positive electrode terminal 14, which are the electrical end portions of the bottom panel row 11R, via the bottom bus bar 20 and the panel row end connector 17. The flexible substrate 30 is disposed in the back side of the bottom panel row 11R and overlaps the bottom solar cell panel 11 in a plan view. The flexible substrate 30 extends in the longitudinal direction (that is, the X direction) of the bottom panel row 11R with a constant width in a plan view.

The flexible substrate 30 is disposed with both main surfaces oriented in the thickness direction. The flexible substrate 30 includes a wiring 31 and a base member 32 that supports the wiring 31. For example, the wiring 31 is formed of a copper foil or the like. The wiring 31 extends over substantially the entire length of the flexible substrate 30. The base member 32 is formed of an insulation material such as polyimide in a sheet shape. The base member 32 exposes the wiring 31 to the front side at both end portions of the flexible substrate 30. The wiring 31 is exposed to the front side from the base member 32 at both end portions of the flexible substrate 30. However, a configuration in which the wiring 31 is exposed on both the front and back sides of the base member 32 by using flying leads near both end portions of the flexible substrate 30 may be used. The wiring 31 is connected to the back surface of the bottom bus bar 20 at both end portions of the flexible substrate 30.

The bypass diode 40 is mounted on the flexible substrate 30. The bypass diode 40 is connected to a middle portion of the wiring 31. The bypass diode 40 performs rectification in the wiring 31. The bypass diode 40 is connected to the back surface of the wiring 31 and protrudes from the flexible substrate 30 to the back side.

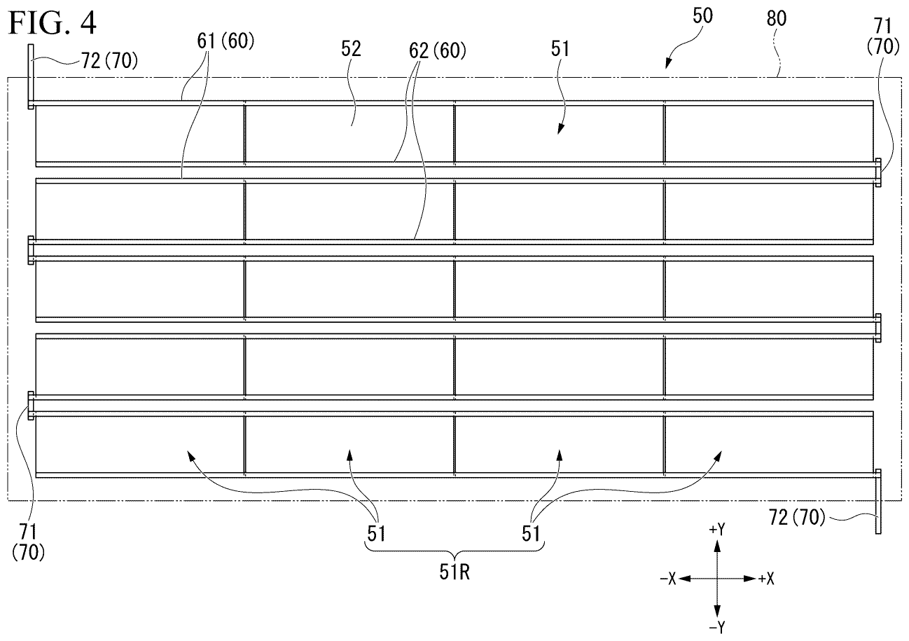

FIG. 4 is a plan view showing the top module of the embodiment. In FIG. 4, the outer shape of the package 80 is indicated by an imaginary line.

As shown in FIG. 4, the top module 50 has a plurality of top solar cell panels 51 (second solar cell panels). All the top solar cell panels 51 are disposed along a common XY plane. The top solar cell panels 51 are provided in the same number as the bottom solar cell panels 11. One photovoltaic cell 52 is formed in the top solar cell panel 51. However, a plurality of photovoltaic cells connected to each other in series and parallel may be formed in the top solar cell panel 51. The photovoltaic cell 52 is a transmission type photovoltaic cell using a direct transition type semiconductor for a light absorbing layer. The photovoltaic cell 52 has a light absorbing layer with a wider bandgap than the light absorbing layer of the photovoltaic cell 12 of the bottom module 10. The light absorbing layer of the photovoltaic cell 52 contains cuprous oxide (Cu₂O) as the direct transition type semiconductor. The photovoltaic cell 52 has a configuration in which a p-electrode, a p-light absorbing layer, an n-compound layer, and an n-electrode are stacked in that order on the front side of a glass substrate. The p-electrode is exposed on the front side at an end portion of the top solar cell panel 51 in the +Y direction. The n-electrode is exposed on the front side at an end portion of the top solar cell panel 51 in the −Y direction. The p-electrode and n-electrode function as terminals for taking out a current on the front side surface of the top solar cell panel 51. The top solar cell panel 51 is disposed with a light receiving surface thereof oriented to the front side. That is, a normal direction of the light receiving surface of the top solar cell panel 51 is the thickness direction.

The top module 50 includes a plurality of top panel rows 51R each formed by a plurality of top solar cell panels 51 connected to each other in parallel. In each top panel row 51R, the top solar cell panels 51 are arranged in the X direction at intervals. The outer shape of the entire top panel row 51R is formed in a rectangular shape with the X direction as a longitudinal direction in a plan view. The top panel rows 51R are connected to each other in series. The top panel rows 51R are arranged in the Y direction at intervals. As a result, the plurality of top solar cell panels 51 are aligned in the X direction and the Y direction. The outer shape of the entire plurality of aligned top solar cell panels 51 is formed in a rectangular shape with the X direction as a longitudinal direction. The top solar cell panels 51 are disposed to overlap the bottom solar cell panels 11 one by one. As a result, in the illustrated example, the top module 50 includes five top panel rows 51R each formed by four top solar cell panels 51.

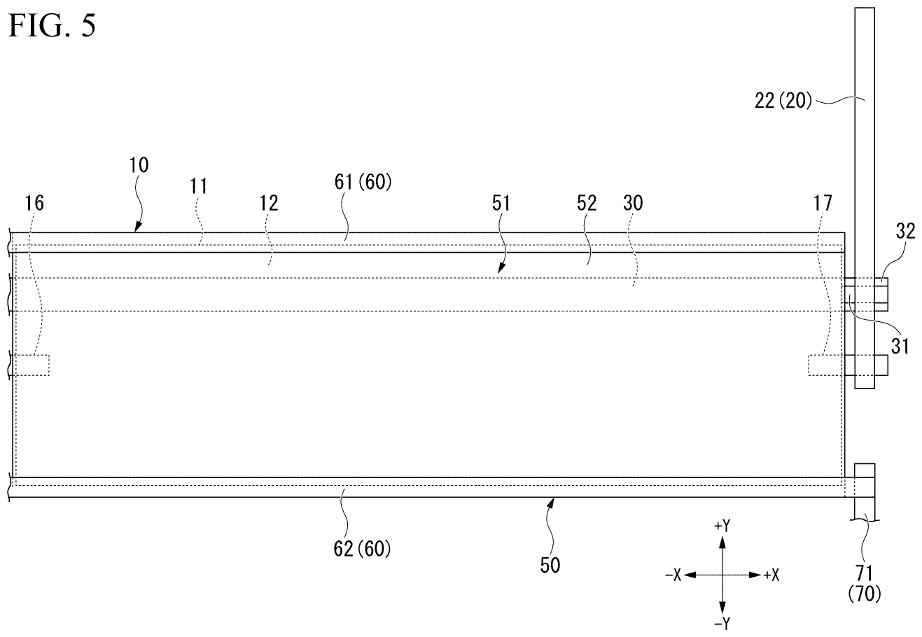

FIG. 5 is a plan view showing a positional relationship between the bottom module and the top module of the embodiment.

As shown in FIG. 5, each top solar cell panel 51 is disposed to face the light receiving surface (the front side surface) of the bottom solar cell panel 11 of the bottom module 10. The top solar cell panel 51 is formed to have a size equal to or greater than that of the bottom solar cell panel 11. The top solar cell panel 51 overlaps the entire bottom solar cell panel 11 in a plan view. The photovoltaic cell 52 of the top solar cell panel 51 overlaps the entire photovoltaic cell 12 of the bottom solar cell panel 11 in a plan view. In other words, the entire photovoltaic cell 12 of the bottom solar cell panel 11 is disposed inside the outline of the photovoltaic cell 52 of the top solar cell panel 51 in a plan view.

As shown in FIG. 4, the top module 50 includes an interconnector 60 and a top bus bar 70. For example, the interconnector 60 is formed of a copper wire, a copper plate, a copper foil, or a conductive tape having solder plated layers on both main surfaces. A pair of interconnectors 60 are provided for each top panel row 51R. The interconnector 60 includes a first interconnector 61 conducted to the p-electrode of the top solar cell panel 51 and a second interconnector 62 conducted to the n-electrode of the top solar cell panel 51 for each top panel row 51R. Each interconnector 60 extends in an alignment direction (that is, the X direction) of the top solar cell panels 51 in the top panel row 51R with a constant width in a plan view. The first interconnector 61 is joined to the surface of an end portion of the top solar cell panel 51 of each top panel row 51R in the +Y direction. The first interconnector 61 connects the p-electrodes of the top solar cell panels 51 of each top panel row 51R to each other. The second interconnector 62 is joined to the surface of an end portion of the top solar cell panel 51 of each top panel row 51R in the −Y direction. The second interconnector 62 connects the n-electrodes of the top solar cell panels 51 of each top panel row 51R to each other. The interconnector 60 is desirably disposed not to overlap the photovoltaic cell 12 of the bottom solar cell panel 11 in a plan view.

The interconnector 60 extends in the +X direction or the −X direction with respect to the top panel row 51R. The first interconnector 61 joined to an odd-numbered top panel row 51R extends in the −X direction with respect to the top panel row 51R. The first interconnector 61 joined to an even-numbered top panel row 51R extends in the +X direction with respect to the top panel row 51R. The second interconnector 62 joined to the odd-numbered top panel row 51R extends in the +X direction with respect to the top panel row 51R. The second interconnector 62 joined to the even-numbered top panel row 51R extends in the −X direction with respect to the top panel row 51R. The interconnector 60 is connected to the top bus bar 70 at a portion that protrudes in the X direction with respect to the top panel row 51R.

The top bus bars 70 are disposed on both sides of the top panel row 51R in the +X direction and the −X direction in a plan view. The top bus bar 70 is disposed in the vicinity of the entire plurality of top solar cell panels 51 in a plan view. In the present embodiment, the vicinity of the entire plurality of top solar cell panels 51 is the vicinity of a single rectangular panel in a case where the plurality of top solar cell panels 51 are regarded as the single rectangular panel. The top bus bar 70 is disposed at same position in the X direction as the bottom bus bar 20. The top bus bar 70 is formed of a metal plate. For example, the top bus bar 70 is formed of the same material as the bottom bus bar 20. The top bus bar 70 extends in the Y direction. The top bus bars 70 are disposed not to come into contact with each other. The top bus bar 70 includes an inter-panel bus bar 71 and a terminal bus bar 72.

The inter-panel bus bar 71 connects the adjacent top panel rows 51R to each other in series via the interconnector 60. The inter-panel bus bars 71 are disposed on both sides of the top panel row 51R in the +X direction and the −X direction in a plan view. The inter-panel bus bar 71 in the +X direction is connected to an end portion of the second interconnector 62 in the +X direction connected to an m-th top panel row 51R and an end portion of the first interconnector 61 in the +X direction connected to an (m+1)-th top panel row 51R, where m is an odd number. The inter-panel bus bar 71 in the −X direction is connected to an end portion of the second interconnector 62 in the −X direction connected to the n-th top panel row 51R and an end portion of the first interconnector 61 in the −X direction connected to an (n+1)-th top panel row 51R, where n is an even number.

When a plurality of top solar cell panels 51 connected to each other in series and parallel are regarded as one solar cell, the terminal bus bar 72 is connected to the p-electrode and the n-electrode, which are the electrical end portions of the one solar cell, via the interconnector 60. The terminal bus bars 72 are disposed on both sides of the top panel row 51R in the +X direction and the −X direction in a plan view. The terminal bus bar 72 in the −X direction is connected to an end portion of the first interconnector 61 in the −X direction connected to a first top panel row 51R. The terminal bus bar 72 in the −X direction extends in the +Y direction from a connecting portion with the first interconnector 61 and is drawn out of the package 80. In a case where the number of top panel rows 51R is N, the terminal bus bar 72 in the +X direction is connected to an end portion of the second interconnector 62 in the +X direction connected to an N-th top panel row 51R. The terminal bus bar 72 in the +X direction extends in the −Y direction from a connecting portion with the second interconnector 62 and is drawn out of the package 80.

Although not shown, a bypass diode may be connected to each top solar cell panel 51 in parallel. For example, one bypass diode can be provided for each top panel row 51R. In this case, the bypass diodes may be connected to the first interconnector 61 and the second interconnector 62 at positions in the +X direction or the −X direction of the top panel row 51R.

As shown in FIG. 1, the package 80 houses the bottom module 10 with the terminal bus bar 22 of the bottom bus bar 20 drawn out and houses the top module 50 with the top bus bar 70 drawn out. The package 80 includes a front cover 81 (a first protective member) and a back cover 82 (a second protective member). The front cover 81 is disposed on the front side of the bottom module 10 and the top module 50. The back cover 82 is disposed on the back side of the bottom module 10 and the top module 50.

The front cover 81 is a single-layer film formed of a fluorine-based resin and having a light-transmitting property. For example, the fluorine-based resin is a tetrafluoroethylene-ethylene copolymer (ETFE), a chlorotrifluoroethylene-ethylene copolymer (ECTFE), or the like. The front cover 81 is formed in a rectangular shape with a pair of sides extending in the X direction and the remaining pair of sides extending in the Y direction in a plan view. The front cover 81 is disposed to overlap all of a portion of the bottom module 10 excluding a tip end of the terminal bus bar 22 and a portion of the top module 50 excluding a tip end of each top bus bar 70 in a plan view. Hereinafter, a portion of each of the bottom module 10 and the top module 50 that overlaps the front cover 81 in a plan view will be referred to as a main portion. The front side surface of the front cover 81 forms a light incidence surface of the tandem type solar cell 1.

Like the front cover 81, the back cover 82 is a single-layer film formed of a fluorine-based resin and having a light-transmitting property. The back cover 82 is formed to have the same shape and size as the front cover 81 in a plan view. The back cover 82 is disposed to completely overlap the front cover 81 in a plan view.

As shown in FIG. 2, the package 80 has a sealing member 83. The sealing member 83 is disposed between the front cover 81 and the back cover 82. The sealing member 83 is formed of a resin material having a light-transmitting property and an insulating property. The sealing member 83 is formed by stacking a plurality of insulation films 90 between the front cover 81 and the back cover 82 and integrating them with each other by a heat treatment. Each insulation film 90 is a single-layer film containing at least one of an ethylene-vinyl acetate copolymer, a polyolefin-based resin, and an ionomer-based resin.

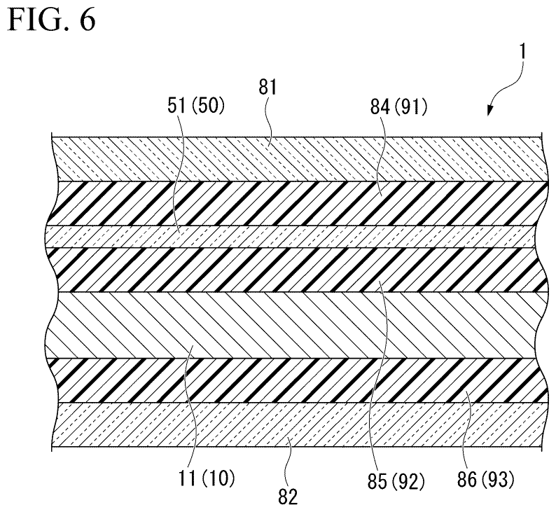

FIG. 6 is a cross-sectional view of the tandem type solar cell along line VI-VI of FIG. 1.

As shown in FIGS. 2 and 6, the plurality of insulation films 90 include a first insulation film 91 (a first sealing member) disposed between the top module 50 and the front cover 81, a second insulation film 92 (a second sealing member) disposed between the bottom module 10 and the top module 50, and a third insulation film 93 (a third sealing member) disposed between the bottom module 10 and the back cover 82. As a result, the bottom module 10 and the top module 50 are disposed between layers of the insulation films 90. The flexible substrate 30 is embedded in the third insulation film 93. Like the front cover 81 and the back cover 82, each insulation film 90 overlaps the entire main portion of each of the bottom module 10 and the top module 50 in a plan view. Furthermore, the insulation films 90 overlap each other at the outside of the bottom module 10 and the top module 50 in a plan view.

As shown in FIG. 6, the sealing member 83 includes a first sealing layer 84, a second sealing layer 85, and a third sealing layer 86. The first sealing layer 84 is stacked to be in direct contact with the top solar cell panel 51 from a side opposite to the bottom solar cell panel 11. The first sealing layer 84 is a portion of the first insulation film 91 that overlaps the top solar cell panel 51 in a plan view. The second sealing layer 85 is disposed between the bottom solar cell panel 11 and the top solar cell panel 51. The second sealing layer 85 is stacked to be in direct contact with the bottom solar cell panel 11 and the top solar cell panel 51. The second sealing layer 85 is a portion of the second insulation film 92 that overlaps the bottom solar cell panel 11 and the top solar cell panel 51 in a plan view. As a result, only the second sealing layer 85 is disposed between the bottom solar cell panel 11 and the top solar cell panel 51. The third sealing layer 86 is stacked to be in direct contact with the bottom solar cell panel 11 from a side opposite to the second sealing layer 85. The third sealing layer 86 is a portion of the third insulation film 93 that overlaps the bottom solar cell panel 11 in a plan view.

The thickness of each component of the tandem type solar cell 1 will be described with reference to FIG. 6.

The thickness of the front cover 81 is 25 μm or more and 200 μm or less, preferably 50 μm or more and 150 μm or less, and more preferably 50 μm or more and 100 μm or less. The thickness of the first sealing layer 84 is 50 μm or more and 400 μm or less, preferably 50 μm or more and 200 μm or less, and more preferably 100 μm or more and 200 μm or less. The thickness of the top solar cell panel 51 is 30 μm or more and 150 μm or less, and preferably 35 μm or more and 80 μm or less. For example, the thickness of the top solar cell panel 51 is the thickness of a glass substrate. The thickness of the second sealing layer 85 is 30 μm or more and 400 μm or less, preferably 35 μm or more and 200 μm or less, and more preferably 100 μm or more and 200 μm or less. The thickness of the bottom solar cell panel 11 is 100 μm or more and 150 μm or less. For example, the thickness of the bottom solar cell panel 11 is the thickness of a silicon wafer (a silicon substrate). The thickness of the third sealing layer 86 is 50 μm or more and 400 μm or less, preferably 50 μm or more and 200 μm or less, and more preferably 100 μm or more and 200 μm or less. In a case where the flexible substrate 30 is embedded in the third sealing layer 86, the thickness of the third sealing layer 86 is a thickness including the flexible substrate 30. The thickness of the back cover 82 is 25 μm or more and 200 μm or less, preferably 50 μm or more and 150 μm or less, and more preferably 50 μm or more and 100 μm or less. Furthermore, the thickness of the tandem type solar cell 1 is 375 μm or more and 1290 μm or less at a portion at which the bottom solar cell panel 11 and the top solar cell panel 51 overlap each other in a plan view. For example, the thickness of each portion of the tandem type solar cell 1 is measured using a cross-sectional SEM or the like.

A method for manufacturing the tandem type solar cell 1 will be described.

In the present embodiment, the tandem type solar cell 1 is formed by heating a stacked body 2 in which the front cover 81, the back cover 82, the bottom module 10, the top module 50, and the insulation film 90 described above are stacked and integrating them with each other. The manufacturing method of the present embodiment includes a preheating step, a stacking step, and a heating step.

First, the preheating step is performed. In the preheating step, at least one of the first insulation film 91, the second insulation film 92, and the third insulation film 93 is heated alone to cause the insulation film to shrink in advance. In the preheating step, it is desirable to arrange a fluororesin sheet between the insulation film to be heated and a heating body to prevent the insulation film from welding to the heating body. The preheating step may not be performed depending on the thickness or material of the protective member or insulation film. Specifically, in the heating step which will be described below, in a case where the thickness of the protective member on a heating surface side of the first protective member and the second protective member is more than 100 μm (preferably 150 μm or more) and in a case where the thickness of the insulation film is more than 100 μm, the preheating step does not need to be performed.

Next, the stacking step is carried out. In the stacking step, the stacked body 2 in which the front cover 81, the first insulation film 91, the top module 50, the second insulation film 92, the bottom module 10, the third insulation film 93, and the back cover 82 are stacked in that order is formed. The top module 50 is disposed such that the top solar cell panel 51 faces the light receiving surface of the bottom solar cell panel 11. The first insulation film 91 overlaps the top module 50 from a side opposite the bottom module 10. A second insulation film 92 overlaps the bottom module 10 and the top module 50 between the bottom solar cell panel 11 and the top solar cell panel 51. The third insulation film 93 overlaps the bottom module 10 from a side opposite to the second insulation film 92. The back cover 82 overlaps the third insulation film 93 from a side opposite to the bottom module 10. The front cover 81 overlaps the first insulation film 91 from a side opposite to the top module 50. In this manner, the stacked body 2 is formed. The order in which the steps of overlapping the members are performed is not particularly limited as long as the stacked body 2 in which the members are stacked in the above-mentioned order can be formed. For example, the front cover 81, the first insulation film 91, the top module 50, the second insulation film 92, the bottom module 10, the third insulation film 93, and the back cover 82 overlap in that order to form the stacked body 2.

Here, the insulation films 90 overlap each other at the outside of the bottom module 10 and the top module 50 in a plan view. As a result, the first insulation film 91 and the second insulation film 92 directly overlap each other at the outside of the top module 50. In addition, the second insulation film 92 and the third insulation film 93 directly overlap each other at the outside of the bottom module 10.

The thickness of each insulation film 90 is 50 μm or more and 400 μm or less, preferably 50 μm or more and 200 μm or less, and more preferably 100 μm or more and 200 μm or less. In a case where the preheating step is performed, the thickness of each insulation film 90 is a thickness before the preheating step. The thickness of each of the front cover 81, the back cover 82, the bottom solar cell panel 11, and the top solar cell panel 51 is the same as each of those of the tandem type solar cell 1 of a finished product.

Next, the heating step is carried out. In the heating step, the stacked body 2 is heated to melt the insulation film 90. The molten insulation film 90 is joined to the member that overlaps the insulation film 90. As a result, the bottom module 10, the top module 50, the front cover 81, the back cover 82, the first insulation film 91, the second insulation film 92, and the third insulation film 93 are joined to each other. In addition, the first insulation film 91 and the second insulation film 92 are welded to each other at the outside of the top module 50 in a plan view to be integrated with each other. Furthermore, the second insulation film 92 and the third insulation film 93 are welded to each other at the outside of the bottom module 10 in a plan view to be integrated with each other. As a result, the first insulation film 91, the second insulation film 92, and the third insulation film 93 are integrated to have continuity, thereby forming the sealing member 83.

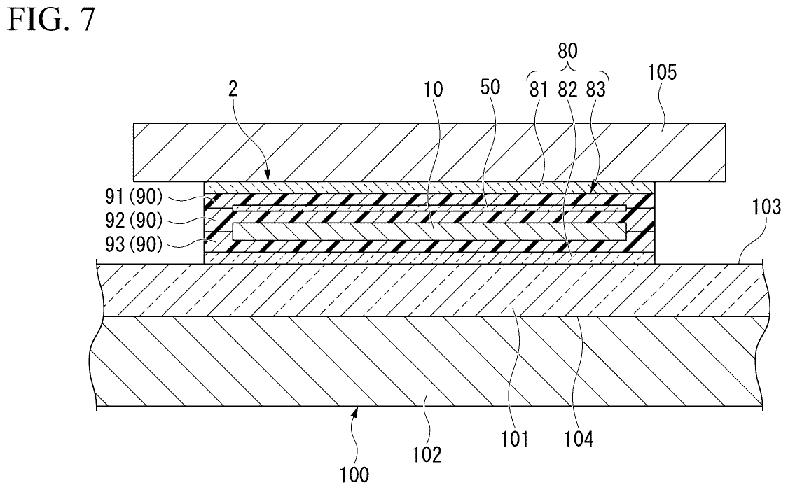

FIG. 7 is a diagram showing an example of the heating step according to an embodiment.

As shown in FIG. 7, in the heating step, the stacked body 2 is heated by bringing a high-temperature heating device 100 into contact with the stacked body 2. The heating device 100 includes a glass body 101 that comes into direct contact with the stacked body 2 and a heater 102 that heats the glass body 101. The glass body 101 is formed of silicate glass. The glass body 101 is, for example, a glass plate. The glass body 101 has a flat heating surface 103 that comes into contact with the front cover 81 or the back cover 82 (the back cover 82 in the illustrated example) of the stacked body 2 and a flat heated surface 104 that faces a side opposite to the heating surface 103. The heating surface 103 is formed to have a size such that it comes into contact with the entire surface of the front cover 81 or the back cover 82. The heater 102 is made of a metal. The heater 102 comes into contact with the heated surface 104 of the glass body 101. It is desirable that the heater 102 come into contact with at least the entire area of the heated surface 104 that coincides with the contact portion between the heating surface 103 and the stacked body 2 when viewed in a normal direction of the heating surface 103. For example, the heater 102 comes into contact with the entire heated surface 104.

In the heating step, the stacked body 2 may be sandwiched between the glass body 101 and a pressing member 105 from both sides in the thickness direction. It is desirable for the pressing member 105 to come into contact with the entire surface of the front cover 81 or the back cover 82 (the front cover 81 in the illustrated example). For example, the pressing member 105 presses the stacked body 2 by its own weight. However, an external force for pressing the stacked body 2 may be applied to the pressing member 105. In addition to heating the stacked body 2 by the heating device 100, the stacked body 2 may be heated by a high-temperature pressing member 105. In this case, the pressing member 105 may be formed by a glass body and a heater, similarly to the heating device 100.

In this manner, the tandem type solar cell 1 is formed. Furthermore, by carrying out the heating step of the present embodiment, the insulation film 90 is melted to form the sealing layers 84, 85, and 86 having the above-mentioned thicknesses.

As described above, the tandem type solar cell 1 of the present embodiment is formed by heating the first insulation film 91, the second insulation film 92, and the third insulation film 93 and joining the bottom module 10, the top module 50, the first insulation film 91, the second insulation film 92, the third insulation film 93, the front cover 81, and the back cover 82 to each other. Here, the thickness of each insulation film 90 is set to 50 μm or more and 400 μm or less, the thickness of the front cover 81 is set to 25 μm or more and 200 μm or less, and the thickness of the back cover 82 is set to 25 μm or more and 200 μm or less. As a result, in the tandem type solar cell 1 of a finished product, the thickness of the first sealing layer 84 is 50 μm or more and 400 μm or less, the thickness of the second sealing layer 85 is 30 μm or more and 400 μm or less, and the thickness of the third sealing layer 86 is 50 μm or more and 400 μm or less. It was checked that by setting the thickness of the tandem type solar cell 1 at the portion at which the bottom solar cell panel 11 and the top solar cell panel 51 overlap in a planar view to 375 μm or more and 1290 μm or less while keeping the thickness of each layer of the tandem type solar cell 1 within the above range, it is possible to form the tandem type solar cell 1 having no wrinkles in the front cover 81 and no deficits in the sealing layers 84, 85, and 86. Therefore, it is possible to suppress a decrease in power generation efficiency of the tandem type solar cell 1 while thinning the tandem type solar cell 1. Therefore, a tandem type solar cell 1 that is highly efficient and lightweight can be obtained.

In particular, if the thickness of the second sealing layer 85 is 30 μm or more, in a case where a material having a volume resistivity of 1.0×10¹⁴ [(Ω·cm] or more is used for the second sealing layer 85, the resistance value in the thickness direction of the second sealing layer 85 will be 3.0×10¹¹ [Ω] or more. Therefore, by setting the thickness of the second sealing layer 85 to 30 μm or more as in the present embodiment, insulation between the bottom solar cell panel 11 and the top solar cell panel 51 can be ensured in the thinned tandem type solar cell 1.

In addition, the thickness of the bottom solar cell panel 11 is set to 100 μm or more and 150 μm or less, and the thickness of the top solar cell panel 51 is set to 30 μm or more and 150 μm or less. As a result, it is possible to ensure bending strength by thinning the solar cell panels 11 and 51, and also ensure strength against thermal stress during heating. Therefore, a thinned tandem type solar cell 1 having excellent practical strength can be obtained.

The front cover 81 is a film containing a fluorine-based resin and having a light-transmitting property. According to this configuration, it is possible to seal each of the top solar cell panel 51 and the bottom solar cell panel 11 while suppressing attenuation of light incident on the top solar cell panel 51 and the bottom solar cell panel 11 and ensuring electrical insulation. In particular, since the front cover 81 of the present embodiment is a single-layer film, the weight of the front cover can be reduced compared to a case where the front cover is a multi-layer film. Therefore, the tandem type solar cell 1 can be made lightweight.

The bottom solar cell panel 11 has an indirect transition type semiconductor layer. The top solar cell panel 51 has a direct transition type semiconductor layer. According to this configuration, the absorption wavelength range of the bottom solar cell panel 11 and the absorption wavelength range of the top solar cell panel 51 can be made different. Therefore, it is possible to form a solar cell having higher efficiency than a solar cell having a solar cell panel having one type of semiconductor layer.

Further, in the top solar cell panel 51, a p-electrode and an n-electrode are formed on the front side of the glass substrate. According to this configuration, even if the second sealing layer 85 between the top solar cell panel 51 and the bottom solar cell panel 11 is thin, electrical insulation between the top solar cell panel 51 and the bottom solar cell panel 11 can be ensured by the glass substrate. Therefore, by thinning the second sealing layer 85, the tandem type solar cell 1 can be made lightweight.

In addition, if the thickness of the glass substrate of the top solar cell panel 51 is 30 μm or more, in a case where the volume resistivity of the glass substrate is 7.9×10¹¹ [Ω·cm] or more, the resistance value in the thickness direction of the glass substrate will be 2.0×10⁹ [Ω] or more. Therefore, insulation between the bottom solar cell panel 11 and the top solar cell panel 51 can be more reliably ensured in the thinned tandem type solar cell 1.

In addition, the method for manufacturing the tandem type solar cell 1 of the present embodiment includes the heating step in which the stacked body 2 formed by the bottom solar cell panel 11, the top solar cell panel 51, the first insulation film 91, the second insulation film 92, the third insulation film 93, the back cover 82, and the front cover 81 is heated by bringing the stacked body 2 into contact with the heated glass body 101. According to this method, since glass has a significantly lower thermal conductivity than a metal material, rapid heat transfer to the stacked body 2 can be suppressed compared to a method in which the stacked body is heated by bringing the stacked body into contact with a heated metal body. For this reason, the stacked body 2 can be heated evenly, and thus the occurrence of local defects in the tandem type solar cell 1 can be suppressed.

In addition, the method for manufacturing the tandem type solar cell 1 of the present embodiment includes the preheating step in which at least one of first insulation film 91, the second insulation film 92, and the third insulation film 93 is heated alone. According to this method, the insulation film that has been thermally shrunk in advance can be used in the heating step, and thus the thermal shrinkage of the insulation film in the heating step can be suppressed, thereby suppressing the occurrence of defects such as wrinkles and deficits in the sealing layers 84, 85, and 86. This is particularly effective in a case where the insulation film is formed of a thermoplastic resin or a material with a relatively large thermal shrinkage rate.

Further, in a case where the thickness of the insulation film that is disposed closest to the heating device 100 in the heating step (the third insulation film 93 in the present embodiment) among the insulation films is 100 μm or less, a deficient portion with a thickness of approximately 30 μm or less, including a step or cavity, can occur after the heating step. As a result, a decrease in the water vapor barrier property of the sealing layer, electrode corrosion, and expansion of air in the defect due to changes in air pressure occur.

Furthermore, in the heating step, in a case where the thickness of the protective member on the heating surface side is greater than 100 μm (preferably 150 μm or more), the shrinkage of the insulation film is suppressed by the firmness of the protective member, but in a case where the thickness of the protective material is 100 μm or less, wrinkles are likely to occur in the insulation film. Therefore, in the heating step, in a case where the thickness of the protective member or the insulation film on the heating surface side in the heating process is 100 μm or less, it is possible to effectively suppress the occurrence of the above-mentioned defects by performing the preheating step, and thus it is preferable to perform the preheating process.

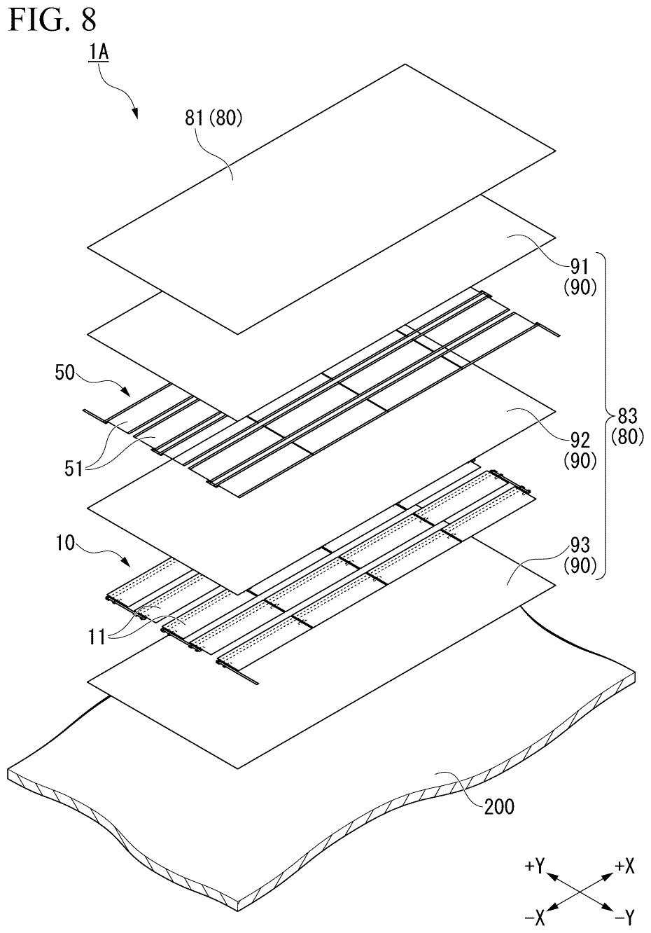

A modification example of the embodiment will be described with reference to FIG. 8. FIG. 8 is a development view of a device including a tandem type solar cell according to the modification example of the embodiment.

In the above embodiment, the sealing member 83 is stacked on the back cover 82. However, as in a tandem type solar cell 1A shown in FIG. 8, the sealing member 83 may be stacked on a part of a device 200 on which the tandem type solar cell 1A is to be mounted, instead of on the back cover 82. In this case, the tandem type solar cell 1A is fixed to the device 200 on which the tandem type solar cell 1A is to be mounted by adhesive or the like. For example, the sealing member 83 is stacked on the upper surface of the wings of an aircraft, the roof of a mobility vehicle, or the like. Even in this case, the thickness of each of the bottom solar cell panel 11, the top solar cell panel 51, the first sealing layer 84, the second sealing layer 85, the third sealing layer 86, and the front cover 81 is the same as in the above embodiment. In addition, the thickness of the tandem type solar cell 1A is 350 μm or more and 1140 μm or less at a portion at which the bottom solar cell panel 11 and the top solar cell panel 51 overlap each other in a plan view. As a result, the tandem type solar cell 1A exhibits the same effects as the tandem type solar cell 1 of the embodiment.

The tandem type solar cell 1A of the present modification example can be formed by the same manufacturing method as the tandem type solar cell 1 of the embodiment. In this case, in the heating step, it is preferable to bring the heating device 100 into contact with the front cover 81 of the stacked body in which the front cover 81, the bottom module 10, the top module 50, and the insulation film 90 are stacked.

In the above embodiment, the front cover 81 is a single-layer film formed of a fluorine-based resin, but the present invention is not limited to this configuration. The front cover may be a single-layer film formed of weather-resistant polyethylene terephthalate. In addition, the front cover may have a structure in which a primer, a top coat, or the like is applied to any of the above-mentioned single-layer films. In addition, the front cover may be a multi-layer film containing at least one of a fluorine-based resin and weather-resistant polyethylene terephthalate. For example, the multi-layer film is a film in which a film made of a fluorine-based resin on the light incident side and a film made of weather-resistant polyethylene terephthalate on the sealing member side are joined together. In any of the above configurations, as long as the front cover is a light-transmitting film containing at least one of the fluorine-based resin and the weather-resistant polyethylene terephthalate, it is possible to seal each of the top solar cell panel 51 and the bottom solar cell panel 11 while suppressing attenuation of light incident on the top solar cell panel 51 and the bottom solar cell panel 11 and ensuring electrical insulation. However, the front cover may be formed of a transparent resin material, glass, or the like other than the above-mentioned materials. The back cover is similar to the front cover.

Further, in the above embodiment, all the bottom solar cell panels 11 are connected to each other in series, but the present invention is not limited to this configuration. The plurality of bottom solar cell panels may be connected to each other in parallel or in a combination of series and parallel. Further, the bottom module may be provided with a single bottom solar cell panel.

Further, in the above embodiment, the plurality of top solar cell panels 51 are connected to each other in a parallel and series combination, but the present invention is not limited this configuration. The plurality of top solar cell panels may be connected to each other in series or parallel. Further, the top module may be provided with a single top solar cell panel.

Further, in the above embodiment, the tandem type solar cell 1 is the four-terminal type solar cell, but the present invention is not limited to this configuration. The tandem type solar cell may be a two-terminal type solar cell in which the bottom module and the top module are connected to each other in series. Furthermore, the positions of the positive electrode terminal and the negative electrode terminal in the tandem type solar cell are not particularly limited.

Further, in the above embodiment, the flexible substrate 30 of the bottom module 10 is disposed on the back side of the bottom solar cell panel 11, but the present invention is not limited to this configuration. For example, the flexible substrate may be disposed in the vicinity of the bottom panel row 11R not to overlap the bottom solar cell panel 11. For example, the flexible substrate may be disposed along the bottom panel row 11R at a position shifted in the Y direction with respect to the bottom panel row 11R connected to the flexible substrate in parallel.

Further, in the above embodiment, the photovoltaic cell 12 of the bottom solar cell panel 11 is the back-contact type photovoltaic cell having an n-type electrode and a p-type electrode on the back side, but the present invention is not limited to this configuration. For example, the photovoltaic cell of the bottom solar cell panel may have a structure having an n-electrode on the front side and a p-electrode on the back side. In this case, the interconnector that connects the pair of bottom solar cell panels may be a wire-like member that connects the p-electrode on the back side of one bottom solar cell panel to the n-electrode on the front side of the other bottom solar cell panel.

According to at least one of the embodiments described above, by setting the thickness at the portion at which the bottom solar cell panel and the top solar cell panel overlap when viewed in the thickness direction to 350 μm or more and 1140 μm or less, it is possible to form the tandem type solar cell having no wrinkles in the front cover and no deficits in the sealing layer. Therefore, it is possible to suppress a decrease in power generation efficiency of the tandem type solar cell while thinning the tandem type solar cell. Therefore, a tandem type solar cell that is highly efficient and lightweight can be obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solar cell comprising:
a first solar cell panel;
a second solar cell panel of a light transmitting type disposed to face a light receiving surface of the first solar cell panel;
a first sealing layer stacked on the second solar cell panel from a side opposite to the first solar cell panel and having a thickness of 50 μm or more and 400 μm or less;
a second sealing layer disposed between the first solar cell panel and the second solar cell panel, stacked to be in direct contact with the first solar cell panel and the second solar cell panel, and having a thickness of 30 μm or more and 400 μm or less;
a third sealing layer stacked on the first solar cell panel from a side opposite to the second sealing layer and having a thickness of 50 μm or more and 400 μm or less; and
a first protective member stacked on the first sealing layer from a side opposite to the second solar cell panel and having a thickness of 25 μm or more and 200 μm or less,
wherein a thickness at a portion at which the first solar cell panel and the second solar cell panel overlap each other when viewed in a normal direction of the light receiving surface of the first solar cell panel is 350 μm or more and 1140 μm or less.

2. The solar cell according to claim 1, further comprising a second protective member stacked on the third sealing layer from a side opposite to the first protective member and having a thickness of 25 μm or more and 200 μm or less,
wherein a thickness at a portion at which the first solar cell panel and the second solar cell panel overlap each other when viewed in a normal direction of the light receiving surface of the first solar cell panel is 375 μm or more and 1290 μm or less.

3. The solar cell according to claim 1,
wherein a thickness of the first solar cell panel is 100 μm or more and 150 μm or less, and
wherein a thickness of the second solar cell panel is 30 μm or more and 150 μm or less.

4. The solar cell according to claim 2,
wherein a thickness of the first solar cell panel is 100 μm or more and 150 μm or less, and
wherein a thickness of the second solar cell panel is 30 μm or more and 150 μm or less.

5. The solar cell according to claim 1,
wherein the first protective member is a light-transmitting film containing at least one of a fluorine-based resin and weather-resistant polyethylene terephthalate, and
wherein each of the first sealing layer, the second sealing layer, and the third sealing layer is a film containing at least one of an ethylene-vinyl acetate copolymer, a polyolefin-based resin, and an ionomer-based resin.

6. The solar cell according to claim 5, wherein the first protective member is a single-layer film.

7. The solar cell according to claim 5, wherein the first protective member is a multi-layer film.

8. The solar cell according to claim 1,
wherein the first solar cell panel has an indirect transition type semiconductor layer, and
wherein the second solar cell panel has a direct transition type semiconductor layer.

9. A solar cell manufacturing method,
wherein a second solar cell panel of a light transmitting type is disposed to face a light receiving surface of the first solar cell panel,
wherein a first sealing member having a thickness of 50 μm or more and 400 μm or less overlaps the second solar cell panel from a side opposite to the first solar cell panel,
wherein a second sealing member having a thickness of 50 μm or more and 400 μm or less overlaps the first solar cell panel and the second solar cell panel between the first solar cell panel and the second solar cell panel,
wherein a third sealing member having a thickness of 50 μm or more and 400 μm or less overlaps the first solar cell panel from a side opposite to the second sealing member,
wherein a first protective member having a thickness of 25 μm or more and 200 μm or less overlaps the first sealing member from a side opposite to the second solar cell panel, and
wherein the first sealing member, the second sealing member, and the third sealing member are heated, the first solar cell panel, the second solar cell panel, the first sealing member, the second sealing member, the third sealing member, and the first protective member are joined to each other, and a thickness at a portion at which the first solar cell panel and the second solar cell panel overlap each other when viewed in a normal direction of the light receiving surface of the first solar cell panel is set to 350 μm or more and 1140 μm or less.

10. The solar cell manufacturing method according to claim 9, comprising a heating step of heating a stacked body in which the first solar cell panel, the second solar cell panel, the first sealing member, the second sealing member, the third sealing member, the first protective member are stacked by bringing the stacked body into contact with a heated glass body.
